(19) United States
(12) Patent Application Publication
(10) Pub. No.: US 2026/0016552 A1
(43) Pub. Date: Jan. 15, 2026

(54) METHOD FOR ADJUSTING SCANNING SEQUENCE FOR MAGNETIC RESONANCE IMAGING SYSTEM, AND SYSTEM

(71) Applicant: GE Precision Healthcare LLC, Waukesha, WI (US)

(72) Inventors: Yao Ding, Beijing (CN); Yongchuan Lai, Beijing (CN); Ting Zhang, Beijing (CN); Xiaocheng Wei, Beijing (CN)

(21) Appl. No.: 19/265,135

(22) Filed: Jul. 10, 2025

(30) Foreign Application Priority Data
Jul. 11, 2024 (CN) 202410928878.5

(51) Int. Cl. G01R 33/54

(52) U.S. Cl. CPC G01R 33/543

(57) ABSTRACT

A magnetic resonance imaging system, and a magnetic resonance imaging method are provided. The method includes: acquiring a scanning sequence for a magnetic resonance imaging system, the scanning sequence including a gradient pulse; and determining a first-type segment of the scanning sequence, in which a peripheral nerve stimulation score exceeds a threshold, maintaining a slew rate of a gradient pulse of the first-type segment, and reducing an absolute value of an amplitude of the gradient pulse of the first-type segment.

### CROSS REFERENCE TO RELATED APPLICATIONS

The present application claims priority and benefit of Chinese Patent Application No. 202410928878.5 filed on Jul. 11, 2024, which is incorporated herein by reference in its entirety.

### TECHNICAL FIELD

Embodiments of the present application relate to the technical field of medical devices, and in particular to a method for adjusting a scanning sequence for a magnetic resonance imaging system, and a system.

### BACKGROUND

Magnetic resonance (MR) imaging systems are widely used in the field of medical diagnostics. Magnetic resonance systems generally have a main magnet, a gradient amplifier, a radio-frequency amplifier, a gradient coil, a transmit chain module, a transmit/receive coil, a receive chain module, etc. The transmit chain module generates a pulse signal and transmits the same to the transmit/receive coil. The transmit/receive coil generates a radio-frequency excitation signal to excite a scanned subject to generate a magnetic resonance signal. After the excitation ends, by means of spatial encoding, the transmit/receive coil acquires the magnetic resonance signal, and the magnetic resonance signal is filled into a k-space, thereby reconstructing a medical image.

In magnetic resonance imaging (MRI), gradient magnetic fields may have a certain influence on scanned subjects (e.g., human bodies, etc.); for example, drastic changes of the gradient magnetic fields may stimulate the sensory nerves and motor nerves of the scanned subjects. This phenomenon is called peripheral nerve stimulation (PNS).

Currently, to reduce PNS, the overall slew rate (SR) of the scanning sequence is reduced. This approach may cause a significant increase in the minimum repetition time (minTR) or echo spacing (ESP) of the scanning sequence, thereby reducing the performance of the MRI system.

Therefore, there is a need for an improved approach that overcomes the limitations of existing bone MRI imaging techniques.

### SUMMARY OF THE INVENTION

According to one aspect of the embodiments of the present application, a method for adjusting a scanning sequence for an MRI system is provided. The method comprises: acquiring a scanning sequence for a magnetic resonance imaging system, the scanning sequence including a gradient pulse; and determining a first-type segment of the scanning sequence, in which a peripheral nerve stimulation score exceeds a threshold, maintaining a slew rate of the gradient pulse of the first-type segment, and reducing an absolute value of an amplitude of the gradient pulse of the first-type segment.

According to an aspect of the embodiments of the present application, a magnetic resonance imaging system is provided, the system comprising: a controller, configured to perform the method for adjusting a scanning sequence for an MRI system described in the previous aspect. and a scanning unit, which performs a scan according to an adjusted scanning sequence, to generate image data.

One of the beneficial effects of the embodiments of the present application is that: when a scanning sequence has a first-type segment in which a peripheral nerve stimulation score exceeds a threshold, a slew rate of a gradient pulse of the first-type segment is maintained, and an absolute value of an amplitude of the gradient pulse of the first-type segment is reduced. As a result, peripheral nerve stimulation in a scanned subject can be reduced, allowing a higher slew rate to be deployed in an MRI system, thereby facilitating reduction of the minimum repetition time (minTR) or echo spacing (ESP) of the scanning sequence, and contributing to performance enhancement of the MRI system.

With reference to the following description and drawings, specific implementations of the embodiments of the present application are disclosed in detail, and the way in which the principles of the embodiments of the present application can be employed are illustrated. It should be understood that the embodiments of the present application are not limited in scope thereby. Within the scope of the spirit and clauses of the appended claims, the embodiments of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of a method for adjusting a scanning sequence for an MRI system according to an embodiment of the present application;

FIG. 3 is a schematic diagram of waveforms of gradient pulses of the scanning sequence according to an embodiment of the present application;

FIG. 4 is another schematic diagram of waveforms of gradient pulses of the scanning sequence according to an embodiment of the present application;

FIG. 5 is another schematic diagram of the method for adjusting a scanning sequence for an MRI system according to an embodiment of the present application;

FIG. 6 is another schematic diagram of the method for adjusting a scanning sequence for an MRI system according to an embodiment of the present application;

FIG. 7 is a schematic diagram of an apparatus for adjusting a scanning sequence for an MRI system according to an embodiment of the present application; and

FIG. 8 is a schematic diagram of an MRI method according to an embodiment of the present application.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc., are used to distinguish different elements with respect to naming, but do not represent a spatial arrangement or temporal order, etc., of these elements, and these elements should not be limited by these terms. The term “and/or” includes any and all combinations of one or more associated listed terms. The terms “comprise”, “include”, “have”, etc., refer to the presence of described features, elements, components, or assemblies, but do not exclude the presence or addition of one or more other features, elements, components, or assemblies.

In the embodiments of the present application, the singular forms “a”, “the”, etc., include plural forms, and should be broadly construed as “a type of” or “a class of” rather than being limited to the meaning of “one”. In addition, the term “the” should be construed as including both the singular and plural forms, unless otherwise specified in the context. In addition, the term “according to” should be construed as “at least in part according to . . . ” and the term “on the basis of” should be construed as “at least in part on the basis of . . . ”, unless otherwise specified in the context.

In the embodiments of the present application, the term “scanned subject” may be equivalently replaced with “subject”, “subject to be scanned”, “subject being scanned”, “patient”, “subject of study”, or the like, and the “scanned subject” may be a living being such as a human being or an animal, or an inanimate object.

In the embodiments of the present application, the term “include/comprise” when used herein refers to the presence of features, integrated components, steps, or assemblies, but does not preclude the presence or addition of one or more other features, integrated components, steps, or assemblies.

The features described and/or illustrated for one implementation may be used in one or more other implementations in the same or similar way, be combined with features in other embodiments, or replace features in other implementations.

For case of understanding, FIG. 1 shows a magnetic resonance imaging (MRI) system 100 according to some embodiments of the present application.

As shown in FIG. 1, the MRI system 100 includes a scanning unit 111. The scanning unit 111 is used to perform a magnetic resonance scan of a subject (e.g., a human body) 170 to generate image data of a region of interest of the subject 170, wherein the region of interest may be a pre-determined anatomical site or anatomical tissue.

The operation of the MRI system 100 is controlled by an operator workstation 110 that includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and in communication with a computer system 120 that enables an operator to control the generation and display of images on the display 118. The computer system 120 includes various components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced by medical imaging functions implemented in the CPU 124. The computer system 120 may be connected to an archive media device, a persistent or backup memory, or a network. The computer system 120 may be coupled to and communicates with a separate MRI system controller 130.

The MRI system controller 130 includes a set of components that communicate with one another via an electrical and/or data connection module 132. The connection module 132 may employ a direct wired connection, a fiber optic connection, a wireless communication link, etc. The MRI system controller 130 may include a CPU 131, a sequence pulse generator (also known as pulse generator) 133 in communication with the operator workstation 110, a calibration module 134 used to calibrate a medical imaging system, a transceiver (also known as RF transceiver) 135, a memory 137, and an array processor 139.

In some embodiments, the sequence pulse generator 133 may be integrated into a resonance assembly 140 of the scanning unit 111 of the MRI system 100. The MRI system controller 130 may receive a command from the operator workstation 110, and is coupled to the scanning unit 111 to indicate an MRI scanning sequence to be performed during an MRI scan, so as to be used to control the scanning unit 111 to perform the flow of the aforementioned magnetic resonance scan. The MRI system controller 130 is further coupled to a gradient driver system (also known as gradient driver) 150 and is in communication therewith, and the gradient driver system is coupled to a gradient coil assembly 142 to generate a magnetic field gradient during an MRI scan.

The sequence pulse generator 133 may further receive data from a physiological acquisition controller 155 that receives signals from a plurality of different sensors (e.g., electrocardiogram (ECG) signals from electrodes attached to a patient, etc.), the sensors being connected to a subject or patient 170 undergoing an MRI scan. The sequence pulse generator 133 is coupled to and in communication with a scan room interface system 145 that receives signals from various sensors associated with the state of the resonance assembly 140. The scan room interface system 145 is further coupled to a patient positioning system 147 and is in communication therewith, and the patient positioning system 147 sends and receives signals to control a patient table (e.g., an examination table) to move to a desired position for an MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} amplifiers excites a corresponding gradient coil in the gradient coil assembly 142, so as to generate a magnetic field gradient used to spatially encode an MR signal during an MRI scan. The gradient coil assembly 142 is disposed within the resonance assembly 140, and the resonance assembly further includes a superconducting magnet having a superconducting coil 144 that, in operation, provides a static uniform longitudinal magnetic field B₀ throughout a cylindrical imaging volume 146. The resonance assembly 140 further includes an RF body coil 148, which, in operation, provides a transverse magnetic field B₁, the transverse magnetic field B₁ being substantially perpendicular to B₀ throughout the entire cylindrical imaging volume 146. The resonance assembly 140 may further include an RF surface coil 149 for imaging different anatomical structures of the patient undergoing the MRI scan. The RF body coil 148 and the RF surface coil 149 may be configured to operate in a transmit and receive mode, a transmit mode, or a receive mode.

The x direction may also be referred to as a frequency encoding direction or a kx direction in the k-space, the y direction may be referred to as a phase encoding direction or a ky direction in the k-space, and the z direction may be referred to as a layer surface (slice) selection (layer selection) direction or layer direction. Gₓ can be used for frequency encoding or signal readout or data readout, and is generally referred to as a frequency encoding gradient or a readout gradient. G_{y} can be used for phase encoding, and is generally referred to as a phase encoding gradient. G_{z} can be used for slice (layer, or layer surface) position selection to acquire k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses amplified by an RF amplifier 162, and provides the same to the RF body coil 148 through a transmit/receive switch (also known as T/R switch or switch) 164.

As described above, the RF body coil 148 and the RF surface coil 149 may be used to transmit RF excitation pulses and/or receive resulting MR signals from the patient undergoing the MRI scan. The MR signals emitted by excited nuclei in the patient of the MRI scan may be sensed and received by the RF body coil 148 or the RF surface coil 149 and sent back to a preamplifier 166 through the T/R switch 164. The T/R switch 164 may be controlled by a signal from the sequence pulse generator 133 to electrically connect the RF amplifier 162 to the RF body coil 148 in the transmit mode and to connect the preamplifier 166 to the RF body coil 148 in the receive mode. The T/R switch 164 may further enable the RF surface coil 149 to be used in the transmit mode or the receive mode.

In some embodiments, the MR signals sensed and received by the RF body coil 148 or the RF surface coil 149 and amplified by the preamplifier 166 are stored in the memory 137 for post-processing as a raw k-space data array. A reconstructed magnetic resonance image may be obtained by transforming/processing the stored raw k-space data.

In some embodiments, the MR signals sensed and received by the RF body coil 148 or the RF surface coil 149 and amplified by the preamplifier 166 are demodulated, filtered, and digitized in a receiving portion of the transceiver 135, and transmitted to the memory 137 in the MRI system controller 130. For each image to be reconstructed, the data is rearranged into separate k-space data arrays, and each of said separate k-space data arrays is input to the array processor 139, the array processor being operated to transform the data into an array of image data by Fourier transform.

The array processor 139 uses transform methods, most commonly Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 1 is intended for illustration. Suitable MRI systems may include more, fewer, and/or different components.

The MRI system controller 130 and the image processor 128 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, medical imaging, etc. For example, the storage medium may store a program used to implement the magnetic resonance imaging method according to the embodiments of the present application. The described storage medium may include, for example, a ROM, a floppy disk, a hard disk, an optical disk, a magneto-optical disk, a CD-ROM, or a non-volatile memory card.

The aforementioned “imaging sequence” (also referred to below as a scanning sequence or a pulse sequence) refers to a combination of pulses having specific amplitudes, widths, directions, and time sequences and applied when a magnetic resonance imaging scan is executed. These pulses may typically include, for example, radio-frequency pulses and gradient pulses. The radio-frequency pulses may include, for example, radio-frequency excitation pulses, radio-frequency refocusing pulses, inverse recovery pulses, etc. The gradient pulses may include, for example, the aforementioned gradient pulse used for layer selection, gradient pulse used for phase encoding, gradient pulse used for frequency encoding, gradient pulse used for phase shifting (phase shift), gradient pulse used for dispersion of phases (dephasing), etc.

Typically, a plurality of scan sequences can be preset in the magnetic resonance system, so that the sequence suitable for clinical detection requirements can be selected. The clinical detection requirements may include, for example, an imaging site, an imaging function, an imaging effect, and the like.

In addition, the aforementioned gradient field can be considered as being oriented both in a physical plane and by the logical axis. In a physical sense, these fields are oriented orthogonally to each other to form a coordinate system, and the coordinate system can be rotated by appropriately manipulating a pulse current applied to an individual gradient field coil.

Thanks to the gradient system, magnetic resonance imaging can be implemented in any direction. Conventional anatomical sites may be scanned using conventional orthoaxial (tri-azimuthal) scans: transverse (TRA) or axial (AX), sagittal (SAG), and coronal (COR) scans. Some special complex sites may be scanned using an oblique scan, for example, a short-axis, four-chamber view is used for a cardiac scan.

In an orthoaxial scan, a physical gradient generated by a gradient amplifier can be configured with respect to an imaging system, so that a physical axis aligns/coincides with the logical axis when imaging is performed in an axial reference plane, a sagittal reference plane, and a coronal reference plane. For example, for axial imaging, coronal imaging, or sagittal imaging, the G_{Z} amplifier can be configured to generate a slice selection gradient, the G_{y}amplifier can be configured to generate a phase-encoding gradient, and the Gₓ amplifier can be configured to generate a frequency-encoding gradient.

When an oblique scan is performed, the logical axis-based coordinate system is rotated by a certain angle relative to the physical axis-based coordinate system. In this case, the slice selection gradient, the frequency-encoding gradient, and the phase-encoding gradient need to be defined in the logical axis-based coordinate system. The slice selection gradient determines a slice of tissue or anatomical structure to be imaged in a patient. Therefore, a slice selection gradient field can be applied simultaneously with a selective radio frequency excitation pulse to excite spin volumes in oblique slices processing at the same frequency. A slice thickness is determined by a bandwidth of the radio frequency excitation pulse and gradient strength in an entire field of view.

Description is made below in conjunction with the embodiments.

Provided in an embodiment of the present application is a method for adjusting a scanning sequence for a magnetic resonance imaging system.

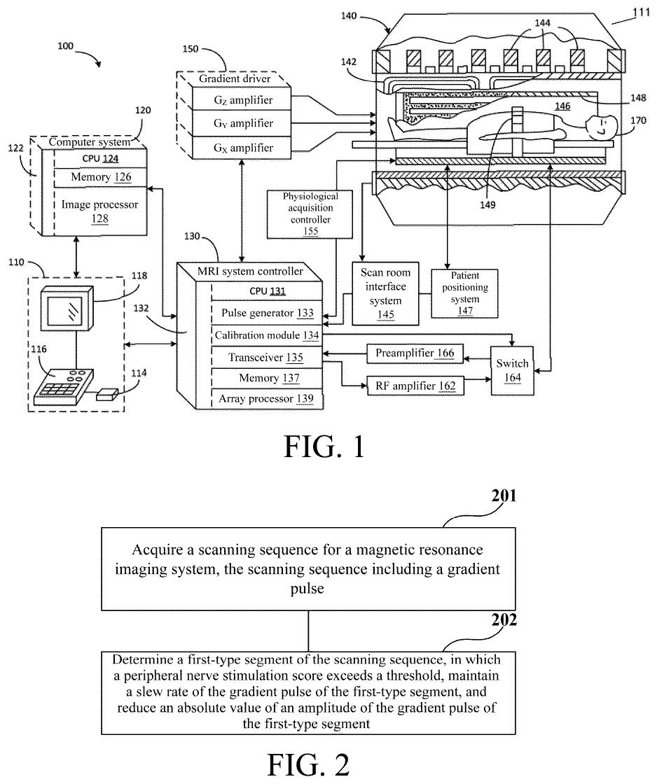

FIG. 2 is a schematic diagram of a method for adjusting a scanning sequence for an MRI system according to an embodiment of the present application. As shown in FIG. 2, the method includes: at Step 201: acquiring a scanning sequence for an MRI system, the scanning sequence including a gradient pulse. The method further includes at step 202: determining a first-type segment of the scanning sequence, in which a peripheral nerve stimulation score exceeds a threshold, maintaining a slew rate of the gradient pulse of the first-type segment, and reducing an absolute value of an amplitude of the gradient pulse of the first-type segment.

According to the described embodiment, when the scanning sequence has the first-type segment in which the peripheral nerve stimulation score exceeds the threshold, the slew rate of the gradient pulse of the first-type segment is maintained, and the absolute value of the amplitude of the gradient pulse of the first-type segment is reduced. As a result, the scanning sequence can be locally derated, thereby reducing a time length during which the amplitude of the gradient pulse of the scanning sequence changes, which can reduce peripheral nerve stimulation for a scanned subject. In the described adjustment approach, there is no need to reduce the slew rate of the gradient pulse of the scanning sequence, which consequently allows a higher slew rate to be deployed in the MRI system, thereby facilitating reduction of the minimum repetition time (minTR) or echo spacing (ESP) of the scanning sequence, and contributing to performance enhancement of the MRI system.

In some embodiments, in step 201, pulse sequences for the MRI system may be acquired in various ways. For example, the scanning sequence may be prestored, or may be generated according to an actual situation.

The scanning sequence may be determined according to a preset scanning protocol, and at least includes a gradient pulse. The gradient pulse may include a first gradient pulse, where the first gradient pulse may include a gradient pulse for phase encoding.

The gradient pulse may further include at least one of a second gradient pulse and a third gradient pulse which are different from the first gradient pulse, where the second gradient pulse may include a gradient pulse for frequency encoding, and the third gradient pulse may include a gradient pulse for layer selection.

In some embodiments, the scanning sequence may take various forms of pulse sequences. For example, the pulse sequences may include a gradient echo (GRE) pulse sequence, a fast spin echo (FSE) pulse sequence, a fast balanced steady-state free precession (bSSFP) sequence, and the like, but the embodiments of the present application are not limited thereto.

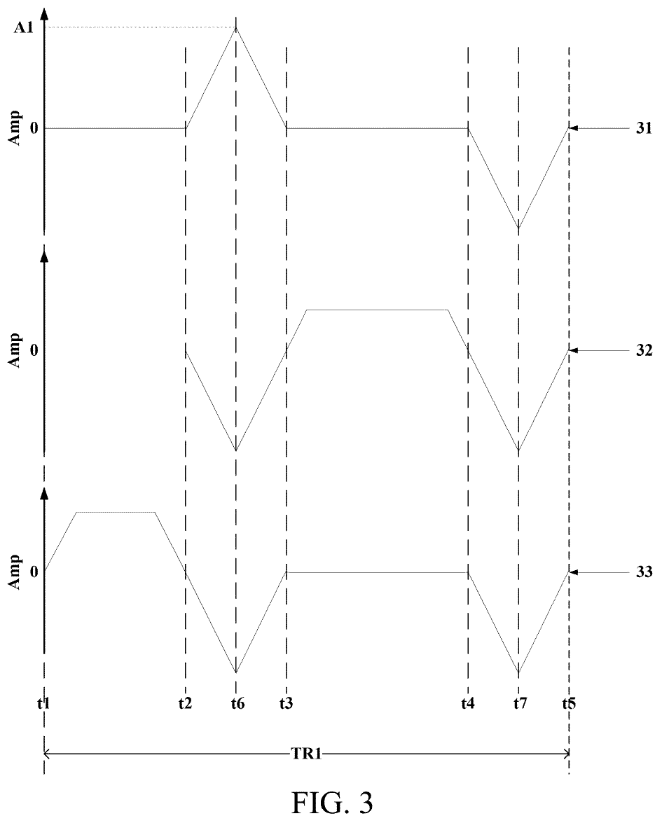

FIG. 3 is a schematic diagram of waveforms of the gradient pulses of the scanning sequence according to an embodiment of the present application. FIG. 3 shows a bSSFP sequence. The following uses a bSSFP sequence as an example to describe the method in the present embodiment of the present application; the method in the present application is also applicable to other types of sequences.

As shown in FIG. 3, the scanning sequence includes a first gradient pulse 31, a second gradient pulse 32, and a third gradient pulse 33. A horizontal axis of the first gradient pulse 31 (i.e., first axis) is a phase encoding gradient axis (also referred to as phase encoding gradient axis or the like), a horizontal axis of the second gradient pulse 32 (i.e., second axis) is a frequency encoding axis (also referred to as frequency encoding gradient axis or the like), and a horizontal axis of the third gradient pulse 33 (i.e., third axis) is a layer direction axis (also referred to as a layer selection gradient axis or the like); and vertical axes of the first gradient pulse 31, the second gradient pulse 32, and the third gradient pulse 33 are amplitude axes.

The scanning sequence may include a plurality of time segments (hereinafter, simply referred to as segments). The segments of the scanning sequence may be divided into functional segments and non-functional segments (also referred to as target segments). The functional segments include, for example, a layer surface selection segment (also referred to as a layer selection segment), a signal readout segment (also referred to as an acquisition segment), and the like. The non-functional segments are, for example, segments other than the functional segments.

In some embodiments, in the functional segments of the scanning sequence, the amplitude of the first gradient pulse 31 may be equal to 0. In other words, the functional segments of the scanning sequence do not include the first gradient pulse 31.

In the functional segments of the scanning sequence, the amplitude of the second gradient pulse 32 or the third gradient pulse 33 is not equal to 0. In other words, the functional segments of the scanning sequence include the second gradient pulse 32 or the third gradient pulse 33.

As shown in FIG. 3, in a segment t1-t2, the scanning sequence includes the third gradient pulse 33 for layer surface selection, and does not include the first gradient pulse 31 for phase encoding or the second gradient pulse 32 for signal readout; accordingly, the segment t1-t2 is a layer surface selection segment.

As shown in FIG. 3, in a segment t3-t4, the scanning sequence includes the second gradient pulse 32 for signal readout, and does not include the first gradient pulse 31 for phase encoding or the third gradient pulse 33 for layer surface selection; accordingly, the segment t3-t4 is a signal readout segment.

In some embodiments, in the non-functional segments of the scanning sequence, the amplitude of the first gradient pulse 31 may not be equal to 0. In other words, the non-functional segments of the scanning sequence include at least the first gradient pulse 31.

As shown in FIG. 3, in a segment t2-t3 and a segment t4-t5, the scanning sequence includes the first gradient pulse 31 for phase encoding, the second gradient pulse 32 for signal readout, and the third gradient pulse 33 for layer surface selection. The segment t2-t3 and the segment t4-t5 are non-functional segments.

The segments of the scanning sequence are exemplarily described above only based on the functional segments and the non-functional segments of the scanning sequence. The present application is not limited thereto, and the segments of the scanning sequence may also have other definitions; for example, a scanning sequence between two adjacent amplitude zero-crossing points (i.e., the amplitude being equal to 0) may be defined as one segment, and the like.

In some embodiments, as shown in FIG. 3, the scanning sequence includes at least one gradient pulse disposed on the gradient axis, for example, the first gradient pulse 31, the second gradient pulse 32, and the third gradient pulse 33.

In some embodiments, the gradient pulse may include a rise phase, in which the amplitude of the waveform of the gradient pulse increases, and a fall phase, in which the amplitude decreases. Additionally, the gradient pulse may further include a plateau phase, in which the amplitude of the waveform of the gradient pulse is unchanged.

In some embodiments, the rate of change of the amplitude of the gradient pulse with respect to time may be referred to as a slew rate (SR). The SR is related to the hardware capability of the MRI system. The higher the SR is, the faster the amplitude changes, and consequently, the smaller the minTR or ESP of the scanning sequence is; and the lower the SR is, the slower the amplitude change, and consequently, the larger the minTR or ESP of the scanning sequence is.

As shown in FIG. 3, using the first gradient pulse 31 as an example, in the segment t2-t6, the first gradient pulse 31 rises from an amplitude of zero to an amplitude A1, and the slew rate of the gradient pulse is calculated as SR=A1/(t6−t2).

As previously mentioned, PNS is caused by a drastic change in a gradient magnetic field. Therefore, PNS is more easily induced in the rise phase and the fall phase of the gradient pulse.

In some embodiments, the intensity of PNS corresponding to the scanning sequence may be described by a PNS score, where the PNS score of the scanning sequence may be determined by various means. The calculation of the PNS score is exemplarily described below.

Reilly proposed a PNS empirical model (also known as the Reilly model) that characterizes a dB/dt threshold for PNS induction in the average population for a given stimulus duration tₛ. The function form of the Reilly model is shown below:

$$\frac{d B}{{dt}_{reilly}} = R \times ( 1 + \frac{C}{{t}_{s}} ) \qquad ( 1 )$$

where tₛ is a duration of the rise phase or fall phase of the waveform of the gradient pulse, i.e., a stimulation time, and R and C are a stimulation threshold and a time constant, respectively, at an infinite stimulation duration.

According to Formula 1, the shorter the duration for rising the amplitude of the gradient pulse from an amplitude zero or falling to a preset amplitude is, or the duration for rising the amplitude of the gradient pulse from the preset amplitude or falling to the amplitude zero is, i.e., the smaller the tₛ, is, the larger the permissible dB/dt threshold is.

In summary, the (dB/dt) threshold for stimulation given in the Reilly model is a stimulation average, that is, the stimulation threshold may induce PNS in some populations but not in others. For populations susceptible to PNS, to avoid PNS, an upper limit of dB/dt for the scanning sequence will be constrained, and to facilitate the control and characterization of the upper limit, dB/dt will generally be normalized to derive a PNS score, which is defined as follows:

$$F = \frac{d B / dt}{{( d B / dt )}_{Reilly}} \qquad ( 2 )$$

when F is 1, the corresponding dB/dt value is equal to a PNS stimulation average of the Reilly model, and when F is greater than 1, the corresponding dB/dt value is greater than the PNS stimulation average of the Reilly model.

In general, a convolution integral model may be used to compute the PNS score for a section (segment) i on an axis j, i.e.:

$${F}_{j} ( {t}_{i} ) = \frac{C}{R} {\sum }_{k = 1}^{i} {\dot{B}}_{j} ( {t}_{k} ) [ \frac{1}{C + {t}_{i} - {t}_{k}} - \frac{1}{C + {t}_{i} - {t}_{k - 1}} ] \qquad ( 3 )$$

where tₖ is an endpoint of time segment k.

The axis j may be any gradient axis among logical axes, for example, a phase encoding gradient axis, a frequency encoding gradient axis, or a layer selection gradient axis.

After the PNS scores for the segments on each axis are calculated, a total PNS score for all axes per time period (segment) may be determined by the following formula:

$$F = \sqrt{{F}_{x}^{2} + {F}_{y}^{2} + {F}_{z}^{2}} \qquad ( 4 )$$

where axes x, y and z are a frequency encoding gradient axis, a phase encoding gradient axis, and a layer selection gradient axis, respectively.

The above is merely an example of calculating the PNS score, and the PNS score may also be calculated in other ways; reference may be made to the related art for details.

In some embodiments, the segments of the scanning sequence may be classified based on the PNS score, and in the first-type segment of the scanning sequence, the amplitude of the first gradient pulse is not equal to 0. For example, in step 202, when the first-type segment of the scanning sequence, in which the PNS score exceeds the threshold, is determined, the PNS scores of all segments of the scanning sequence may be calculated, and non-functional segments in which the PNS scores exceed the threshold are selected as first-type segments. The present application is not limited thereto, and when the first-type segment of the scanning sequence, in which the PNS score exceeds the threshold, is determined, only the PNS scores of the non-functional segments may be calculated, and the non-functional segments in which the PNS scores exceed the threshold are selected as the first-type segments.

In some embodiments, a threshold of the PNS score may be a value less than or equal to 1. The threshold may also be referred to as a dB/dt limit or a PNS limit. The smaller the threshold is, the lower the permissible PNS is; and the larger the threshold is, the higher the permissible PNS is. For example, an operator may set a plurality of thresholds. For scanned subjects having lower tolerance, a smaller threshold may be selected; and for scanned subjects having higher tolerance, a larger threshold may be selected.

In some embodiments, for the first-type segment, in which the PNS score exceeds the threshold, the slew rate of the gradient pulse of the first-type segment may be maintained, and the absolute value of the amplitude of the gradient pulse of the first-type segment may be reduced.

As shown in FIG. 3, the first-type segments of the scanning sequence may be, for example, t2-t3 and t4-t5, and for the two first-type segments, a limit may be imposed on each gradient pulse of the scanning sequence, that is, the absolute value of the amplitude of the gradient pulse is reduced.

In some embodiments, before the absolute value of the amplitude is reduced, the waveform of the gradient pulse of the first-type segment includes a first phase, in which the absolute value of the amplitude increases, and a second phase, in which the absolute value of the amplitude decreases. After the absolute value of the amplitude is reduced, the waveform of the gradient pulse of the first-type segment includes a third phase, in which the absolute value of the amplitude increases, and a fourth phase, in which the absolute value of the amplitude decreases. A duration of the third phase is shorter than a duration of the first phase, and a duration of the fourth phase is shorter than a duration of the second phase.

In this way, a duration over which the amplitude of the gradient pulse changes, i.e., a stimulation duration, is reduced, and thus, PNS can be reduced, so that the PNS score does not exceed the threshold.

In some embodiments, after the gradient pulse of the first-type segment is derated, a duration of a plateau of the waveform of the gradient pulse of the first-type segment may be adjusted according to an extent of reduction for the absolute value of the amplitude.

For example, the duration of the plateau may be adjusted as follows: an area of the waveform of the gradient pulse of the first-type segment before the absolute value of the amplitude is reduced is a first value, the area of the waveform of the gradient pulse of the first-type segment after the absolute value of the amplitude is reduced is a second value, and the first value is equal to the second value.

For example, after the absolute value of the amplitude of the gradient pulse of the first-type segment is reduced, in order to ensure that the area of the gradient pulse is equal to an area before the gradient pulse is derated, the duration of the plateau of the gradient pulse may be appropriately extended.

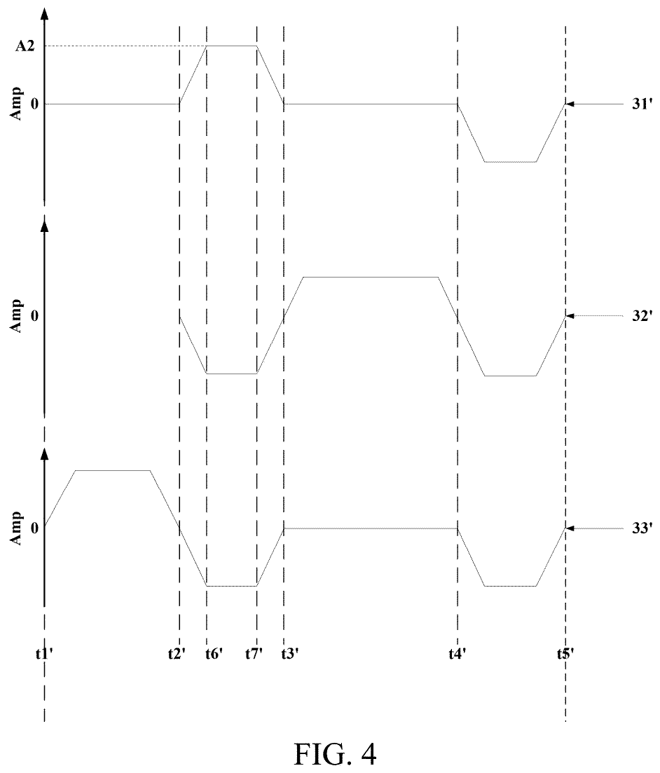

FIG. 4 is another schematic diagram of the waveforms of the gradient pulses of the scanning sequence according to an embodiment of the present application. FIG. 4 shows a scanning sequence obtained after the scanning sequence shown in FIG. 3 is partially derated. As shown in FIG. 3 and FIG. 4, the first gradient pulse 31, the second gradient pulse 32 and the third gradient pulse 33 in FIG. 3 are adjusted to a first gradient pulse 31′, a second gradient pulse 32′ and a third gradient pulse 33′ in FIG. 4, respectively.

Using the first-type segment t2-t3 of the first gradient pulse 31 of the scanning sequence in FIG. 3 as an example, a maximum amplitude of the gradient pulse is A1; and as shown in FIG. 4, the first-type segment t2-t3 of the first gradient pulse 31 is adjusted to a segment t2′-t3′, and in the segment t2′-t3′, a maximum amplitude of the gradient pulse is A2, where A2 is less than A1.

In FIG. 3, an SR of the first gradient pulse 31 in the segment t2-t6 is SR1; and in FIG. 4, an SR of the first gradient pulse 31 in the segment t2′-t6′ is SR2, where SR1=SR2. This avoids reducing the SR of the scanning sequence, thereby allowing greater utilization of the hardware performance of the MRI system.

In some embodiments, the SRs of the respective segments of the scanning sequence may be equal. In this way, a consistent slew rate can be maintained, and the generation of more gradient power and heat can be avoided. In a case where the SRs of the respective segments of the scanning sequence before undergoing derating adjustment are equal, the SRs of the respective segments of the scanning sequence after adjustment in the described manner are also equal. Thus, additional gradient power and heat can be reduced while avoiding reducing the SR of the scanning sequence.

In some embodiments, in FIG. 3, the area of the first gradient pulse 31 in the segment t2-t3 is S1; and in FIG. 4, the area of the first gradient pulse 31′ in the segment t2′-t3′ is S2, where S1=S2.

As shown in FIG. 3 and FIG. 4, since the amplitude of the segment t2-t3 of the first gradient pulse 31 is reduced, in order to make the area unchanged, a duration of a plateau t6′-t7′ of the segment t2′-t3′ of the first gradient pulse 31′ may be determined according to A1 and A2.

Similarly, for a segment t4′-t5′, the waveform of this segment may also be determined in a similar manner.

As shown in FIG. 3 and FIG. 4, for other segments, in which the PNS score does not exceed the threshold, the waveforms of the other segments may be maintained. That is, the waveform of each gradient pulse in the segment t1-t2 is the same as the waveform in the segment t1′-t2′, and the waveform of each gradient pulse in the segment t3-t4 is the same as the waveform in the segment t3′-t4′.

In some embodiments, for a first-type segment, in which the PNS score exceeds the threshold, an extent of reduction for the absolute value of the amplitude of the gradient pulse may be determined in various manners. For example, the extent of reduction may be determined in an iterative manner.

For example, the absolute value of the amplitude of the gradient pulse may be reduced by a preset step size, for example, the absolute value of the amplitude of the gradient pulse is reduced from a first value to a second value, and the PNS score of the scanning sequence after the absolute value of the amplitude is reduced is calculated; and if there is no first-type segment in which the PNS score exceeds the threshold, the second value is used as the absolute value of the adjusted amplitude, otherwise, the absolute value of the amplitude is continuously reduced by a preset step size, for example, the absolute value of the amplitude is reduced from the second value to a third value. The above process is repeated until no first-type segments exist in the scanning sequence.

In some embodiments, the step size in the described iteration process may be a preset value. The present application is not limited thereto, and the step size may also correspond to a degree of difference between the PNS score and the threshold. For example, the step size may be proportional to the difference between the PNS score and the threshold; that is, the larger the difference between the PNS score and the threshold is, the larger the step size is, and the smaller the difference between the PNS score and the threshold is, the smaller the step size is.

In some embodiments, for a segment in which the amplitude of the first gradient pulse is equal to 0, e.g., a functional segment, the amplitude of the gradient pulse of the segment corresponds to a corresponding function, and if the amplitude of the gradient pulse of the segment is changed, the completeness of the function corresponding to the segment may be affected. Thus, if the PNS score of a functional segment exceeds the threshold, the amplitude of the gradient pulses of the functional segment may be maintained, and the slew rate of the gradient pulses of the segment can be reduced. In this way, the PNS of the segment can be reduced.

In some embodiments, in order to ensure that the overall slew rate of the scanning sequence is consistent, the SRs of other segments of the scanning sequence may also be reduced while the SR of the gradient pulse of the functional segment is reduced.

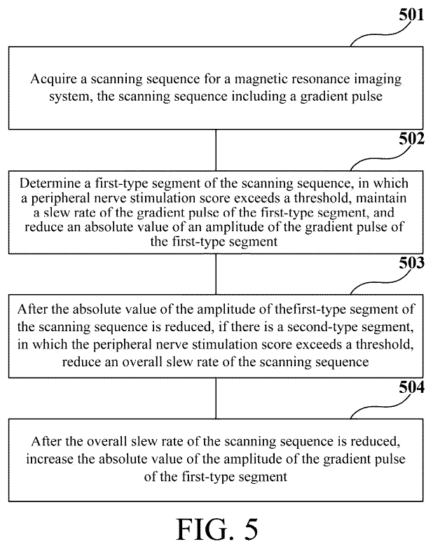

FIG. 5 is another schematic diagram of the method for adjusting a scanning sequence for an MRI system according to an embodiment of the present application. As shown in FIG. 5, the method includes: acquiring a scanning sequence for an MRI system at step 501, the scanning sequence including a gradient pulse. The method also includes a step 502 for determining a first-type segment of the scanning sequence in which a peripheral nerve stimulation score exceeds a threshold, maintaining a slew rate of the gradient pulse of the first-type segment, and reducing an absolute value of an amplitude of the gradient pulse of the first-type segment. Finally, the method includes a step 503: after the absolute value of the amplitude of the first-type segment of the scanning sequence is reduced, if there is a second-type segment in which the peripheral nerve stimulation score exceeds a threshold, reducing an overall slew rate of the scanning sequence.

This ensures that the PNS score of each segment of the scanning sequence does not exceed the threshold. Moreover, in step 502, the PNS of the first-type segment has been reduced by means of local derating, and when the PNS of the second-type segment is reduced by means of reducing the SR, the SR will not be greatly reduced.

Steps 501 and 502 are the same as steps 201 and 202, and their contents are merged here without further elaboration.

In step 503, the reduced SR may be determined by various means. For example, a similar manner as determining the reduced magnitude of the amplitude of the gradient pulse may be employed. For example, the reduced SR may be determined in an iterative manner. The iterative step size may be a preset value, or correspond to a degree of difference between the PNS score and the threshold.

In some embodiments, in the second-type segment of the scanning sequence, the amplitude of the first gradient pulse is equal to 0.

In some embodiments, in the second-type segment of the scanning sequence, the amplitude of the second gradient pulse or the third gradient pulse is not equal to 0.

In some embodiments, as shown in FIG. 5, the method may further include a step 504: after the overall slew rate of the scanning sequence is reduced, increasing the absolute value of the amplitude of the gradient pulse of the first-type segment.

It is assumed that the PNS score of the first-type segment after step 502 is V1, where V1 is less than the threshold. Since the slew rates of the respective segments (including the first-type segment) of the scanning sequence are reduced in step 503, a PNS score V2 of the first-type segment is a value smaller than V1 after step 503. In this case, the absolute value of the amplitude of the gradient pulse of the first-type segment may be increased by an appropriate amplitude, so that a PNS score V3 of the first-type segment after step 504 is a value greater than V2 and less than the threshold. This helps to further reduce the minTR and ESP of the scanning sequence.

In step 504, an amount of absolute value increase for the amplitude of the gradient pulse may be determined by various means. For example, a similar manner as determining the reduced magnitude of the amplitude of the gradient pulse may be employed. For example, the amount of increase may be determined in an iterative manner. The iterative step size may be a preset value, or correspond to a degree of difference between the PNS score and the threshold.

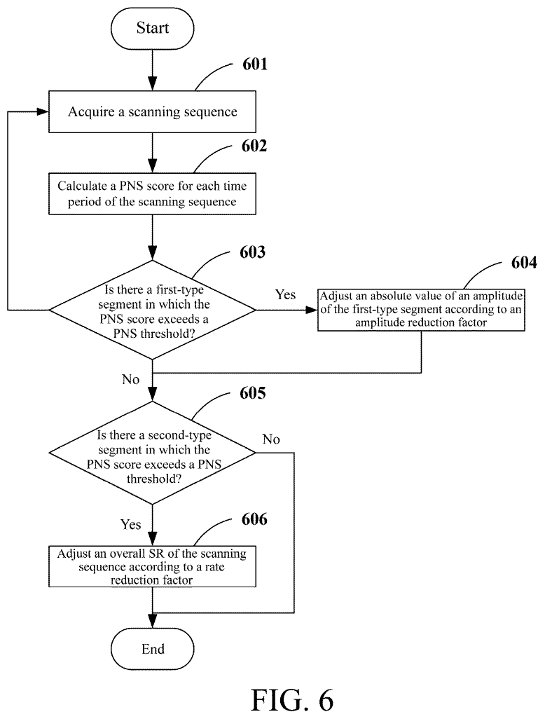

FIG. 6 illustrates a method for adjusting a scanning sequence in an MRI system according to an embodiment of the present application. In step 601, a scanning sequence is acquired, with its slew rate (SR) initially set to the maximum supported by the MRI hardware. Then, in step 602, a peripheral nerve stimulation (PNS) score is calculated for each time period of the sequence. At step 603, the method checks for any non-functional segment (first-type segment) where the PNS score exceeds a defined threshold. If such a segment exists, then in step 604, the amplitude of that segment is reduced using a predefined or iteratively determined amplitude reduction factor, which may be less than 1 in an embodiment, resulting in a new amplitude equal to the original amplitude multiplied by this factor.

If no first-type segment is identified, the method proceeds to step 605 to determine whether any functional segment (second-type segment) exceeds the PNS threshold. If so, then in step 606, the overall slew rate of the scanning sequence is adjusted using a rate reduction factor, which may also be predefined or determined iteratively. In one embodiment, the rate reduction factor may be than 1, and the adjusted slew rate is equal to the product of the original slew rate and the rate reduction factor.

According to the described embodiment, when the scanning sequence has the first-type segment in which the peripheral nerve stimulation score exceeds the threshold, the slew rate of the gradient pulse of the first-type segment is maintained, and the absolute value of the amplitude of the gradient pulse of the first-type segment is reduced. As a result, the scanning sequence can be locally derated, thereby reducing a time length during which the amplitude of the gradient pulse of the scanning sequence changes, which can reduce peripheral nerve stimulation for a scanned subject. In the described adjustment approach, there is no need to reduce the slew rate of the gradient pulse of the scanning sequence, which consequently allows a higher slew rate to be deployed in the MRI system, thereby facilitating reduction of the minimum repetition time (minTR) or echo spacing (ESP) of the scanning sequence, and contributing to performance enhancement of the MRI system.

The embodiments of the present application further provide an apparatus for adjusting a scanning sequence for an MRI system.

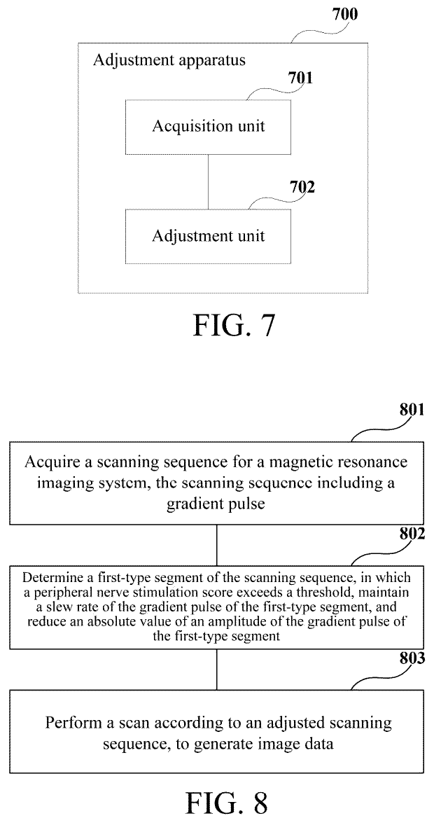

FIG. 7 is a schematic diagram of an apparatus for adjusting a scanning sequence for an MRI system according to an embodiment of the present application. As shown in FIG. 7, the apparatus 700 includes: an acquisition unit 701 and an adjustment unit 702. The acquisition unit 701 acquires a scanning sequence for an MRI system, the scanning sequence including a gradient pulse. The adjusting unit 702 determines a first-type segment of the scanning sequence in which a peripheral nerve stimulation score exceeds a threshold, maintains a slew rate of the gradient pulse of the first-type segment, and reduces an absolute value of an amplitude of the gradient pulse of the first-type segment.

In some embodiments, the scanning sequence includes a first gradient pulse, and in the first-type segment of the scanning sequence, an amplitude of the first gradient pulse is not equal to 0.

In some embodiments, the first gradient pulse includes a gradient pulse for phase encoding.

In some embodiments, before the absolute value of the amplitude is reduced, a waveform of the gradient pulse of the first-type segment includes a first phase, in which the absolute value of the amplitude increases, and a second phase, in which the absolute value of the amplitude decreases; after the absolute value of the amplitude is reduced, the waveform of the gradient pulse of the first-type segment includes a third phase, in which the absolute value of the amplitude increases, and a fourth phase, in which the absolute value of the amplitude decreases, a duration of the third phase being shorter than a duration of the first phase, and a duration of the fourth phase being shorter than a duration of the second phase.

In some embodiments, a duration of a plateau of the waveform of the gradient pulse of the first-type segment is adjusted according to an extent of reduction for the absolute value of the amplitude.

In some embodiments, an area of the waveform of the gradient pulse of the first-type segment before the absolute value of the amplitude is reduced is a first value, the area of the waveform of the gradient pulse of the first-type segment after the absolute value of the amplitude is reduced is a second value, and the first value is equal to the second value.

In some embodiments, after the absolute value of the amplitude of the first-type segment of the scanning sequence is reduced, if there is a second-type segment in which the peripheral nerve stimulation score exceeds a threshold, an overall slew rate of the scanning sequence is reduced.

In some embodiments, the scanning sequence includes a first gradient pulse, and in the second-type segment of the scanning sequence, an amplitude of the first gradient pulse is equal to 0.

In some embodiments, the scanning sequence further includes a second gradient pulse and a third gradient pulse, and in the second-type segment of the scanning sequence, an amplitude of the second gradient pulse or the third gradient pulse is not equal to 0.

For the specific implementation, reference may be made to the foregoing embodiments, which will not be repeated here.

The embodiments of the present application further provide a magnetic resonance imaging method.

FIG. 8 is a schematic diagram of an MRI method according to an embodiment of the present application. As shown in FIG. 8, the method includes at step 801: acquiring a scanning sequence for an MRI system, the scanning sequence including a gradient pulse. The method further includes a step 802 for determining a first-type segment of the scanning sequence in which a peripheral nerve stimulation score exceeds a threshold, maintaining a slew rate of the gradient pulse of the first-type segment, and reducing an absolute value of an amplitude of the gradient pulse of the first-type segment. Finally at step 803, a scan is performed according to an adjusted scanning sequence, to generate image data.

The gradient pulse of the scanning sequence before adjustment is an initial gradient pulse, and the adjusted gradient pulse is an optimized gradient pulse. In step 803, the image data is generated by performing a scan according to the scanning sequence including the optimized gradient pulse, which can reduce PNS for the scanned subject, and can allow a higher slew rate to be deployed in the magnetic resonance imaging system, thereby facilitating reduction of the minimum repetition time (minTR) or echo spacing (ESP) of the scanning sequence, and contributing to performance enhancement of the magnetic resonance imaging system.

For the specific implementation, reference may be made to the foregoing embodiments, which will not be repeated here.

The embodiments of the present application further provide a magnetic resonance imaging system. The configuration of the magnetic resonance imaging system is as shown in FIG. 1, and similarities are not repeated here.

In some embodiments, unlike the foregoing MRI system in FIG. 1, the controller 130 is configured to perform the foregoing MRI method.

In some embodiments, the controller 130 (which may also be a processor) includes a computer processor and a storage medium, the storage medium having recorded thereon a predetermined data processing program to be executed by the computer processor. For example, the storage medium may store a program used to implement scanning processing (e.g., including waveform design/conversion, etc.), image reconstruction, image processing, etc. For example, the storage medium may store a program used to implement the scanning sequence adjusting method for a magnetic resonance imaging system or the magnetic resonance imaging method according to the embodiments of the present application. The specific implementations thereof are as described above, and will not be repeated here.

The described storage medium may include, for example, a ROM, a floppy disk, a hard disk, an optical disk, a magneto-optical disk, a CD-ROM, or a non-volatile memory card.

Further provided in the embodiments of the present application is a computer-readable program, where the program, when executed in an apparatus or an MRI system, causes a computer to execute, in the apparatus or the MRI system, the method according to the foregoing embodiments.

Further provided in the embodiments of the present application is a storage medium having a computer-readable program stored therein, where the computer-readable program causes a computer to execute, in an apparatus or an MRI system, the method according to the foregoing embodiments.

Further provided in the embodiments of the present application is a computer program product at least including a computer program, where the computer program, when executed by a processor, causes an apparatus or an MRI system to execute the method according to the foregoing embodiments.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a disk, an optical disk, a DVD, a flash memory, etc.

The method/apparatus described in view of the embodiments of the present application may be directly embodied as hardware, a software module executed by a processor, or a combination of the two. For example, one or more of the functional block diagrams and/or one or more combinations of the functional block diagrams shown in the drawings may correspond to either respective software modules or respective hardware modules of a computer program flow. The foregoing software modules may respectively correspond to the steps shown in the figures. The foregoing hardware modules can be implemented, for example, by firming the software modules using a field-programmable gate array (FPGA).

The software modules may be located in a RAM, a flash memory, a ROM, an EPROM, an EEPROM, a register, a hard disk, a portable storage disk, a CD-ROM, or any other form of storage medium known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, the software modules can be stored in the MEGA-SIM card or the large-capacity flash memory apparatus.

One or more of the functional blocks and/or one or more combinations of the functional blocks shown in the accompanying drawings may be implemented as a general-purpose processor, a digital signal processor (DSP), an application-specific integrated circuit (ASIC), a field-programmable gate array (FPGA) or other programmable logic devices, discrete gate or transistor logic devices, a discrete hardware assembly, or any appropriate combination thereof for implementing the functions described in the present application. The one or more functional blocks and/or the one or more combinations of the functional blocks shown in the accompanying drawings may also be implemented as a combination of computing devices, such as a combination of a DSP and a microprocessor, multiple microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A method for adjusting a scanning sequence for a magnetic resonance imaging system, wherein the method comprises:
acquiring a scanning sequence for a magnetic resonance imaging system, the scanning sequence comprising a gradient pulse; and
determining a first-type segment of the scanning sequence in which a peripheral nerve stimulation score exceeds a threshold, maintaining a slew rate of a gradient pulse of the first-type segment, and reducing an absolute value of an amplitude of the gradient pulse of the first-type segment.

2. The method according to claim 1, wherein,
the scanning sequence comprises a first gradient pulse, and in the first-type segment of the scanning sequence, an amplitude of the first gradient pulse is not equal to 0.

3. The method according to claim 2, wherein,
the first gradient pulse comprises a gradient pulse for phase encoding.

4. The method according to claim 1, wherein,
before the absolute value of the amplitude is reduced, a waveform of the gradient pulse of the first-type segment comprises a first phase, in which the absolute value of the amplitude increases, and a second phase, in which the absolute value of the amplitude decreases;
after the absolute value of the amplitude is reduced, a waveform of the gradient pulse of the first-type segment comprises a third phase, in which the absolute value of the amplitude increases, and a fourth phase, in which the absolute value of the amplitude decreases; and
a duration of the third phase is shorter than a duration of the first phase, and a duration of the fourth phase is shorter than a duration of the second phase.

5. The method according to claim 1, wherein,
a duration of a plateau of the waveform of the gradient pulse of the first-type segment is adjusted according to an amount of reduction for the absolute value of the amplitude.

6. The method according to claim 1, wherein,
an area of the waveform of the gradient pulse of the first-type segment before the absolute value of the amplitude is reduced is a first value,
an area of the waveform after the absolute value of the amplitude is reduced of the gradient pulse of the first-type segment is a second value, and
the first value and the second value are equal.

7. The method according to claim 1, wherein the method further comprises:
after the absolute value of the amplitude of the first-type segment of the scanning sequence is reduced, when there is a second-type segment in which the peripheral nerve stimulation score exceeds a threshold, reducing an overall slew rate of the scanning sequence.

8. The method according to claim 7, wherein,
the scanning sequence comprises a first gradient pulse, and in the second-type segment of the scanning sequence, an amplitude of the first gradient pulse is equal to 0.

9. The method according to claim 8, wherein,
the scanning sequence further comprises a second gradient pulse and a third gradient pulse, and in the second-type segment of the scanning sequence, an amplitude of the second gradient pulse or the third gradient pulse is not equal to 0.

10. A magnetic resonance imaging system, characterized by comprising:
a controller, configured to perform the method for adjusting a scanning sequence for a magnetic resonance imaging system according to claim 1; and
a scanning unit, which performs a scan according to an adjusted scanning sequence, to generate image data.
